(19) United States
(12) Patent Application Publication
(10) Pub. No.: US 2017/0052739 A1
(43) Pub. Date: Feb. 23, 2017

(54) STORAGE CONTROL DEVICE, STORAGE DEVICE, AND STORAGE CONTROL METHOD

(71) Applicant: SONY CORPORATION, TOKYO (JP)

(72) Inventor: HARUHIKO TERADA, Kanagawa (JP)

(21) Appl. No.: 15/307,360

(22) PCT Filed: Apr. 10, 2015
(86) PCT No.: PCT/JP2015/061235

§ 371 Date: Oct. 27, 2016

(30) Foreign Application Priority Data
May 9, 2014 (JP) 2014-097257

(51) Int. Cl. G06F 3/06; G11C 13/00

(52) U.S. Cl. CPC G06F 3/0659; G06F 3/0613; G06F 3/0673; G11C 13/0069; G11C 13/004; G11C 13/0097

(57) ABSTRACT

When reading and writing are successively performed at the same address, the access to the storage area is streamlined.

A memory reading unit reads data stored at a predetermined address in a memory array, and stores the data read from the memory array into a read data holding unit, the data read from the memory array being stored as read data. A read data outputting unit outputs the read data stored in the read data holding unit to a requester. A memory writing unit performs writing at a write target address in the memory array in accordance with the write data to be written into the memory array and the read data. A control unit controls the memory writing unit to operate only when the write target address matches the address of the read data.

### CROSS REFERENCE TO RELATED APPLICATION

This application is a U.S. National Phase of International Patent Application No. PCT/JP2015/061235 filed on Apr. 10, 2015, which claims priority benefit of Japanese Patent Application No. JP 2014-097257 filed in the Japan Patent Office on May 9, 2014. The above-referenced application is hereby incorporated herein by reference in its entirety.

### TECHNICAL FIELD

The present technology relates to a storage control device. More particularly, the present technology relates to a storage control device that streamlines access to a storage area, a storage device, a storage control method to be implemented in the storage control device, and a program for causing a computer to implement the method.

### BACKGROUND ART

In a resistance random access memory that is a kind of nonvolatile memory, a current pulse or a voltage pulse is applied so that the resistance values of memory cells are changed, and information is recorded. There are differences in the polarity of voltage or current and in size between a pulse for switching a cell from a low resistive state to a high resistive state and a pulse for switching a cell from a high resistive state to a low resistive state. If a pulse for switching a cell to a low resistive state is applied to a cell already in a low resistive state, the characteristics of the cell might be degraded. The same goes for a cell in a high resistive state. In view of this, when writing is performed on such a memory cell, it is preferable to perform such control that any pulse is not applied to the cell if the current state of the cell that has been read before write pulse application is the same as the value to be written into the cell. As such control is performed, the life of the cell can be extended, and power to be consumed by unnecessary pulse application can be eliminated. For example, a semiconductor memory device has been suggested by making use of the concept of a phase-change memory that uses resistance changes. To perform writing on memory cells, this semiconductor memory device reads the current values, and applies a write pulse only to the bits into which different values from the current values are to be written (see Patent Document 1, for example).

### CITATION LIST

### Patent Document

Patent Document 1: Japanese Patent Application Laid-Open No. 2010-244607

### SUMMARY OF THE INVENTION

### Problems to be Solved by the Invention

By the above described conventional technology, the current values are read before writing is performed on memory cells, to avoid unnecessary pulse application. However, immediately after data is read, new data might be written at the same address. In such a case, the same data is read twice in a row, which is an unnecessary operation. Such situations occur in wear leveling and data swapping, and high-speed processing is required for these operations in practice.

The present technology has been developed in view of those circumstances, and aims to streamline access to the storage area when reading and writing are successively performed at the same address.

### Solutions to Problems

The present technology has been developed to solve the above problems, and a first aspect thereof lies in a storage device that includes: a memory reading unit that reads data stored at a predetermined address in a memory array, and stores the data read from the memory array into a read data holding unit, the data read from the memory array being stored as read data; a read data outputting unit that outputs the read data stored in the read data holding unit to the requester; a memory writing unit that performs writing at a write target address in the memory array in accordance with write data to be written into the memory array and the read data; and a control unit that controls the memory writing unit to operate only when the write target address matches the predetermined address. The first aspect of the present technology also lies in a storage control method. With this, the need for a pre-read process before writing is effectively eliminated.

Also, in the first aspect, when a command for sequentially performing reading and writing at the same address in the memory array is issued, the control unit may determine that the write target address matches the predetermined address.

Also, in the first aspect, when a command for outputting the read data stored in the read data holding unit to the requester is issued, the control unit may determine that the write target address matches the predetermined address.

Also, in the first aspect, when a command for performing writing without storing new data with respect to the write target address into the read data holding unit is issued, the control unit may determine that the write target address matches the predetermined address.

Also, in the first aspect, the control unit may include an address match detecting unit that detects a match between the write target address and the predetermined address, and determine whether the write target address matches the predetermined address.

Meanwhile, a second aspect of the present technology lies in an information processing system that includes: a storage device, a memory controller that controls a request for access to the storage device, and a host computer that issues an access command for the storage device to the memory controller. The storage device includes: a memory reading unit that reads data stored at a predetermined address in a memory array, and stores the data read from the memory array into a read data holding unit, the data read from the memory array being stored as read data; a read data outputting unit that outputs the read data stored in the read data holding unit to the requester; a memory writing unit that performs writing at a write target address in the memory array in accordance with write data to be written into the memory array and the read data; and a control unit that controls the memory writing unit to operate only when the write target address matches the predetermined address. With this, the need for a pre-read process before writing is performed in accordance with a request from the host computer is effectively eliminated.

### Effects of the Invention

According to the present technology, it is possible to achieve an excellent effect to streamline access to the storage area when reading and writing are successively performed at the same address. It should be noted that effects of the present technology are not limited to the effects described above, and may include any of the effects described in the present disclosure.

### BRIEF DESCRIPTION OF DRAWINGS

FIG. 1 is a diagram showing an example configuration of a memory system according to an embodiment of the present technology.

FIG. 2 is a graph showing the resistive state of a resistive random access memory as an example of a nonvolatile memory in an NVM array 311 according to the embodiment of the present technology.

FIG. 3 is a diagram showing an example of a truth table of a comparator 314 according to the embodiment of the present technology.

FIG. 4 is a flowchart showing an example of a sense operation of the NVM array 311 according to the embodiment of the present technology.

FIG. 5 is a flowchart showing an example of a program operation of the NVM array 311 according to the embodiment of the present technology.

FIG. 6 is a table showing an example of the address space in a storage device 300 according to the embodiment of the present technology.

FIG. 7 is a flowchart showing an example of the procedures for processing a read command in a storage device 300 according to the embodiment of the present technology.

FIG. 8 is a timing chart showing an example of the procedures for processing a read command in a storage device 300 according to the embodiment of the present technology.

FIG. 9 is a flowchart showing an example of the procedures for processing a write command in a storage device 300 according to the embodiment of the present technology.

FIG. 10 is a timing chart showing an example of the procedures for processing a write command in a storage device 300 according to the embodiment of the present technology.

FIG. 11 is a flowchart showing an example of the procedures for processing a RW command in a storage device 300 according to the first embodiment of the present technology.

FIG. 12 is a timing chart showing an example of the procedures for processing a RW command in a storage device 300 according to the first embodiment of the present technology.

FIG. 13 is a flowchart showing an example of the procedures in a command reception process to be performed by a memory controller 200 according to the first embodiment of the present technology.

FIG. 14 is a flowchart showing an example of the procedures in a command transmission process to be performed by the memory controller 200 according to the first embodiment of the present technology.

FIG. 15 is a flowchart showing an example of the procedures for processing a DATAOUT command in a storage device 300 according to a second embodiment of the present technology.

FIG. 16 is a timing chart showing an example of the procedures for processing a DATAOUT command in a storage device 300 according to the second embodiment of the present technology.

FIG. 17 is a flowchart showing an example of the procedures for processing a BW command in a storage device 300 according to a third embodiment of the present technology.

FIG. 18 is a timing chart showing an example of the procedures for processing only a BW command in a storage device 300 according to the third embodiment of the present technology.

FIG. 19 is a timing chart showing an example of the procedures for processing a BW command immediately after a read command in a storage device 300 according to the third embodiment of the present technology.

FIG. 20 is a table showing an example configuration of a read address detection register 327 according to a fourth embodiment of the present technology.

FIG. 21 is a flowchart showing an example of the procedures in a process to be performed by the IF 320 of a storage device 300 according to the fourth embodiment of the present technology.

FIG. 22 is a timing chart showing an example of the procedures in a high-speed write process according to the fourth embodiment of the present technology.

FIG. 23 is a flowchart showing an example of the procedures in a process to be performed by a memory controller 200 according to a sixth embodiment of the present technology.

FIG. 24 is a flowchart showing an example of the procedures in a process to be performed by a memory controller 200 according to a seventh embodiment of the present technology.

### MODES FOR CARRYING OUT THE INVENTION

The following is a description of modes for carrying out the present technology (the modes will be hereinafter referred to as the embodiments). Explanation will be made in the following order.

1. First embodiment (an example where RW command is used)

2. Second embodiment (an example where DATAOUT command is used)

3. Third embodiment (an example where BW command is used)

4. Fourth embodiment (an example where detection by a memory device is regarded as a trigger)

5. Fifth embodiment (an example where a host computer issues commands)

6. Sixth embodiment (an example application of data swapping)

7. Seventh embodiment (an example application of refreshing)

### 1. First Embodiment

### [Configuration of a Memory System]

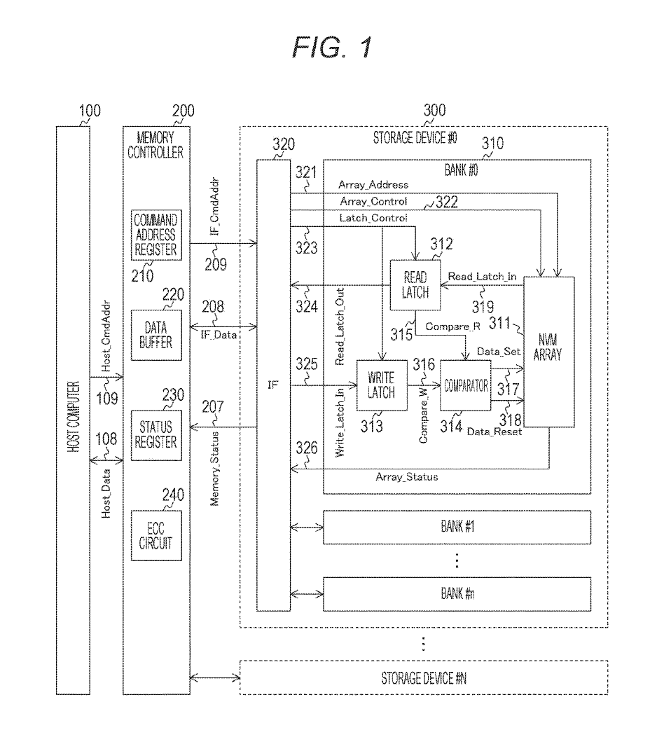

FIG. 1 is a diagram showing an example configuration of a memory system according to an embodiment of the present technology. It should be noted that in this diagram and the other diagrams, only the circuit configuration and the signal lines relevant to the respective embodiments are shown, but the memory system also includes other necessary circuits and signal lines.

This memory system includes a host computer 100, a memory controller 200, and one or more storage devices 300. Each storage device 300 includes an interface (IF) 320 and one or more banks 310.

The host computer 100 issues a command to request a data read process or a data write process to be performed on a storage device 300. This host computer 100 successively transmits a command that designates an operation of the memory controller 200, and an address indicating the operation target of the command, through a Host_CmdAddr signal line 109. This host computer 100 also performs data transmission and reception to and from the memory controller 200 through a Host_Data signal line 108.

The memory controller 200 communicates with the host computer 100 to receive the command, and accesses the storage device 300. This memory controller 200 includes a command address register 210 that temporarily stores the command and the address received through the Host_CmdAddr signal line 109. This memory controller 200 also includes a data buffer 220 that temporarily stores the received data. This memory controller 200 also includes a status register 230 that stores the internal state of the storage device 300 received through a Memory_Status signal line 207. This memory controller 200 also includes an ECC circuit 240 that performs data error detection and correction.

This memory controller 200 transmits a command that designates various operations of the storage device 300, and the address of the operation target, to the IF 320 in the storage device 300 through an IF_CmdAddr signal line 209. The memory controller 200 then performs data transmission and reception to and from the IF 320 via an IF_Data signal line 208. This memory controller 200 also receives the internal state of the storage device 300 from the IF 320 through the Memory_Status signal line 207, and stores the internal state into the status register 230.

Each bank 310 includes a nonvolatile memory (NVM) array 311, a read latch 312, a write latch 313, and a comparator 314. The NVM array 311 is a storage area that stores data. This NVM array 311 has a structure formed with a large number of nonvolatile memory cells arranged in a two- or three-dimensional lattice, and peripheral circuits that control those memory cells. The read latch 312 and the write latch 313 are circuits for temporarily saving data at a time of access to the NVM array 311. The read latch 312 and the write latch 313 may be formed with latch circuits, flip-flop circuits, SRAMs, or the like. The comparator 314 is formed with a logic gate, and is a circuit for comparing the contents of the read latch 312 with the contents of the write latch 313, and generating reference signals (a Data_Set signal line 317 and a Data_Reset signal line 318) at a time of pulse application by the NVM array 311.

It should be noted that although the read latch 312, the write latch 313, and the comparator 314 are provided in a bank 310 of a storage device 300 in this embodiment, these components may be provided in the memory controller 200.

Also, the IF 320 described above is an example of the control unit of the claims, but the memory controller 200 may have the functions of the control unit.

### [Characteristics of the NVM Array]

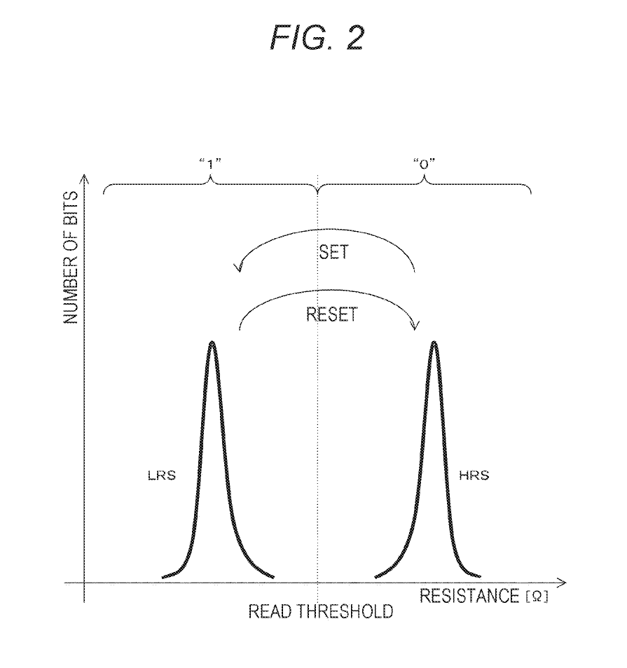

FIG. 2 is a graph showing the resistive state of a resistive random access memory as an example of a nonvolatile memory in the NVM array 311 according to an embodiment of the present technology.

A memory cell of a resistive random access memory switches to a low resistive state (LRS) through a set operation, and switches to a high resistive state (HRS) through a reset operation. The resistive state is reversibly switched between a low resistive state and a high resistive state so that a nonvolatile memory that can store 1 bit with one memory cell is obtained. In this embodiment, HRS is defined as a state where “0” is recorded, and LRS is defined as a state where “1” is recorded, for example.

A set operation is performed by applying a voltage (or current) pulse called a set pulse to both ends of one memory cell. A reset operation is performed by applying a voltage (or current) pulse called a reset pulse to both ends of one memory cell.

### [Comparator]

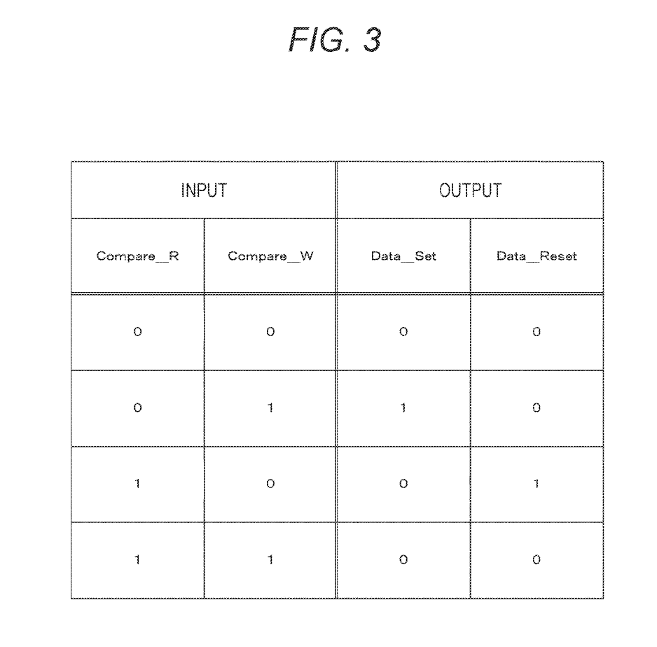

FIG. 3 is a diagram showing an example of a truth table of the comparator 314 according to the embodiment of the present technology. In a case where the value to be written (Compare_W) is the same as the existing value (Compare_R), the comparator 314 outputs “0” to both the Data_Set signal line 317 and the Data_Reset signal line 318. In a case where Compare_W differs from Compare_R, on the other hand, “1” is output only to the Data_Set signal line 317 if Compare_W is 1, and “1” is output only to the Data_Reset signal line 318 if Compare_W is 0.

It should be noted that although each input/output of the comparator 314 is one bit in the example shown in the drawing, each input/output of the comparator 314 may be two or more bits. In that case, operations based on the above described truth table are performed on the respective bits of each input/output in parallel.

### [Operation of the NVM Array]

The NVM array 311 according to the embodiment of the present technology operates a memory cell designated through an Array-Address signal line 321 in accordance with the value of an Array Control signal line 322 from the IF 320.

The NVM array 311 includes data input buses (the Data Set signal line 317 and the Data_Reset signal line 318) necessary for setting or resetting a memory cell. The NVM array 311 also includes a bus (a Read_Latch_In signal line 319) that outputs data read from a memory cell. The NVM array 311 also notifies the IF 320 of its own state through an Array_Status signal line 326.

The NVM array 311 recognizes “Sense” and “Program” as signals of the Array_Control signal line 322, and does nothing when a signal other than the above is input.

When the Array_Status signal line 326 indicates “Ready”, the IF 320 outputs “Sense” or “Program” as a signal of the Array_Control signal line 322. By doing so, the IF 320 causes the NVM array 311 to start a new sense operation or a new program operation.

When the Array_Status signal line 326 indicates “Programming” or “Sensing”, the IF 320 is prohibited from outputting “Sense” or “Program” to the Array_Control signal line 322.

It should be noted that the Read_Latch_In signal line 319 is an example of the memory reading unit of the claims.

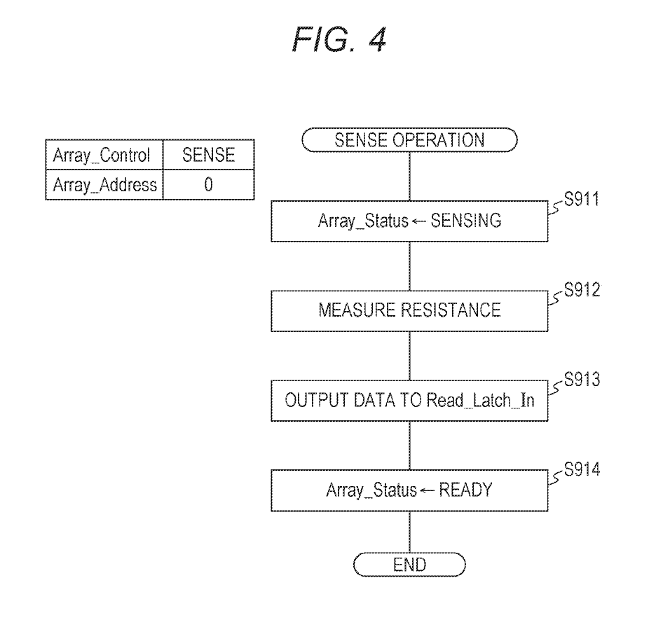

FIG. 4 is a flowchart showing an example of a sense operation of the NVM array 311 according to the embodiment of the present technology. This sense operation starts when “Sense” is output from the IF 320 to the Array_Control signal line 322.

First, the NVM array 311 sets the Array Status signal line 326 at “Sensing” (step S911). The NVM array 311 then refers to the address value (“0” in the example shown in the drawing) output to the Array-Address signal line 321, measures the resistance value of the memory cell at the corresponding address, and determines its logical value by comparing the resistance value with a read threshold (step S912). The data read in this manner is output to the Read_Latch_In signal line 319 (step S913).

The NVM array 311 sets the Array_Status signal line 326 at “Ready”, and the sense operation is then completed (step S914).

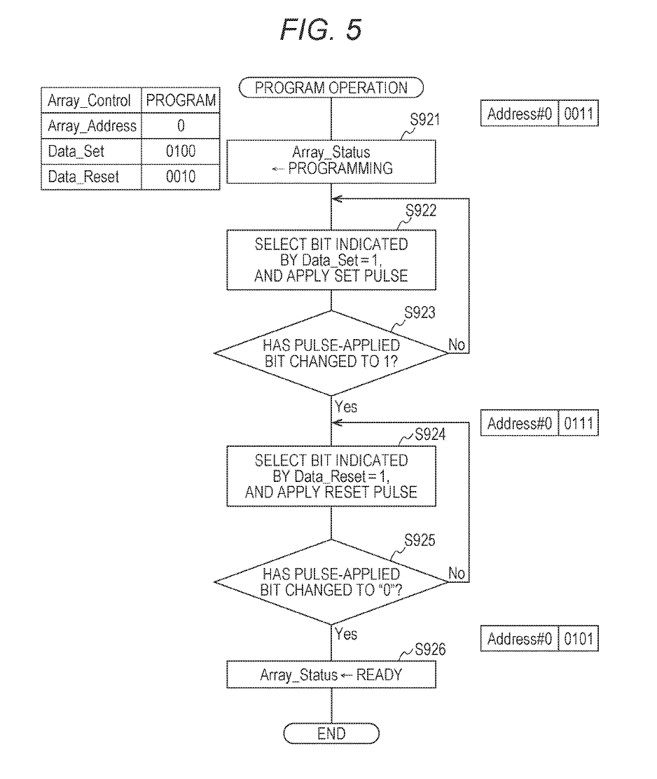

FIG. 5 is a flowchart showing an example of a program operation of the NVM array 311 according to the embodiment of the present technology. This program operation starts when “Program” is output as an Array_Control signal from the IF 320. For example, the address (Array_Address) of the operation target is “0”, and the value already written at an address #0 is “0011”. Also, the Data_Set signal line 317 is set at “0100”, and the Data_Reset signal line 318 is set at “0010”.

First, the NVM array 311 sets the Array_Status signal line 326 at “Programming” (step S921). The NVM array 311 then refers to the Data_Set signal line 317, selects only the bit indicated by the value of the Data_Set signal line 317 from the bit string at the address #0, and applies the set pulse to the selected bit (step S922). Since the Data_Set signal line 317 is “0100” in this example, only the second highest bit is selected, and the address #0 is rewritten from “0111” to “0111”. The resistance of the bit having the pulse applied thereto is then measured, and a check is made to determine whether “1” is readout. If the resistance change caused by the set pulse is incomplete, and “1” has not been read out (No in step S923), the set pulse is again applied.

The NVM array 311 then refers to the Data_Reset signal line 318, selects only the bit indicated by the value of the Data_Reset signal line 318 from the bit string at the address #0, and applies the reset pulse to the selected bit in a similar manner to above (step S924). A check is then made to determine whether “0” is appropriately read out. If “0” has not been read out (No in step S924), the reset pulse is again applied. Since the Data_Reset signal line 318 is “0010” in this example, only the third highest bit is selected, and the address #0 is rewritten from “0111” to “0101”.

The NVM array 311 sets the Array_Status signal line 326 at “Ready”, and the program operation is then completed (step S926).

### [Address Space]

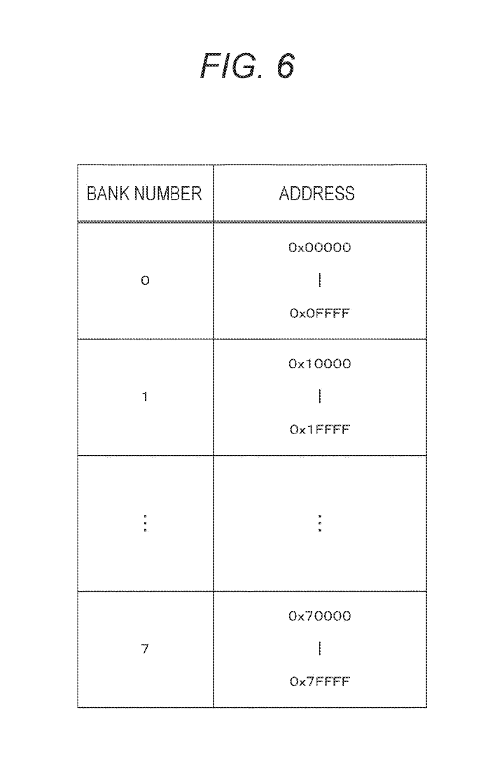

FIG. 6 is a table showing an example of the address space in a storage device 300 according to the embodiment of the present technology. The address indicated by the IF_CmdAddr signal line 209 in this embodiment includes a bank number and numbers uniquely assigned to the respective minimum access units of the NVM array 311 in the bank. A minimum access unit is 1K byte, for example.

An address is formed with 19 bits in total, the higher three bits indicate the bank number, and the lower 16 bits indicate the address in the bank. One storage device 300 includes eight (the cube of 2) banks, and one bank includes 65536 (2 to the 16th power) addresses. Here, the recording capacity per storage device 300 is 8×65536×1K bytes=512M bytes.

### [Commands]

Access from the memory controller 200 to a storage device 300 is performed with a combination of the three commands: a read command, a write command, and a RW command. The respective operations will be described below. It should be noted that a RW command is an example of the command for successively performing reading from the memory array and writing at the same address as disclosed in the claims.

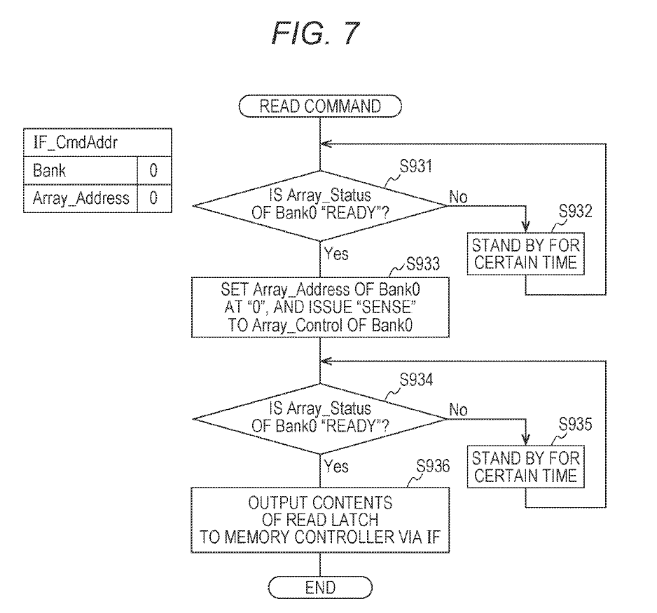

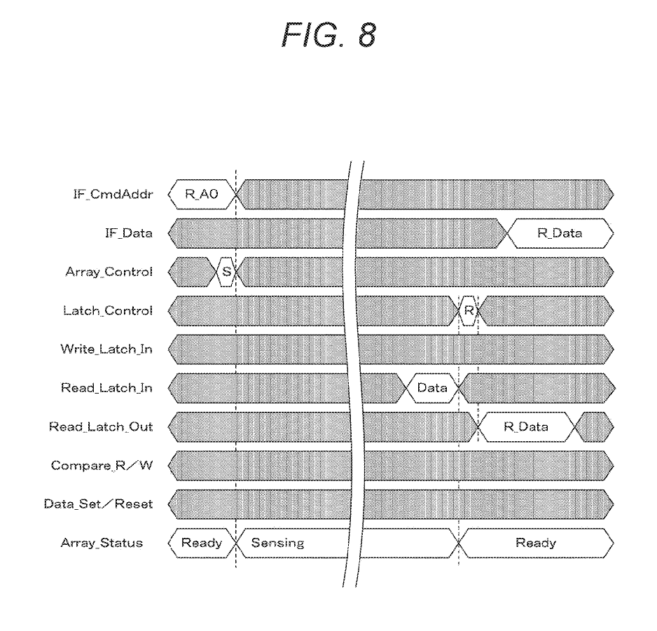

FIG. 7 is a flowchart showing an example of the procedures for processing a read command in a storage device 300 according to the embodiment of the present technology. Also, FIG. 8 is a timing chart showing an example of the procedures for processing a read command in a storage device 300 according to the embodiment of the present technology. In this example case, an address designated by the IF_CmdAddr signal line 209 is the address #0 in a bank #0.

When the memory controller 200 outputs a read command and the address #0 (represented by “R_A0” in the chart) to the IF CmdAddr signal line 209, processing of the read command starts. First, the IF 320 refers to the Array_Status signal line 326 of the bank #0, and stands by until the value of the Array_Status signal line 326 switches to “Ready” (steps S931 and S932). When the Array_Status signal line 326 switches to “Ready” (Yes in step S931), the IF 320 outputs “0” to the Array-Address signal line 321 of the bank #0, and “Sense” (represented by “S” in the chart) to the Array_Control signal line 322 (step S933). As a result, the NVM array 311 starts a sense operation, and the Array_Status signal line 326 switches to “Sensing”.

After a certain time has passed, data read from the NVM array 311 is output to the Read_Latch_In signal line 319, and is stored into the read latch 312. When the data output to the Read_Latch_In signal line 319 is completed, the Array_Status signal line 326 switches to “Ready”.

The IF 320 stands by until the Array_Status signal line 326 switches to “Ready” (steps S934 and S935). When the Array_Status signal line 326 switches to “Ready” (Yes in step S934), a control signal “R” is output to a Latch_Control signal line 323, and the read data stored in the read latch 312 is read out via a Read_Latch_Out signal line 324. The IF 320 then outputs the read data to the memory controller 200 via the IF_Data signal line 208 (step S936).

It should be noted that the Read_Latch_Out signal line 324 is an example of the read data outputting unit of the claims.

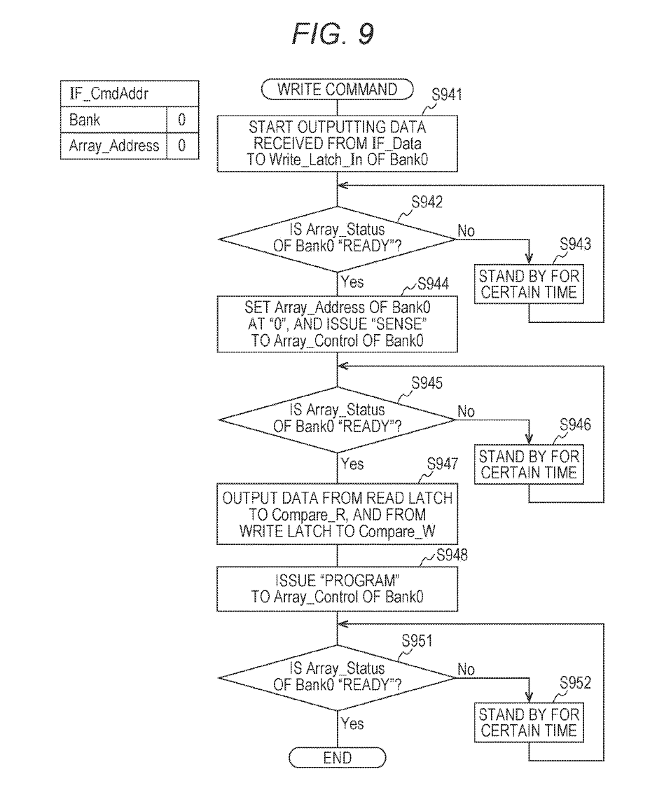

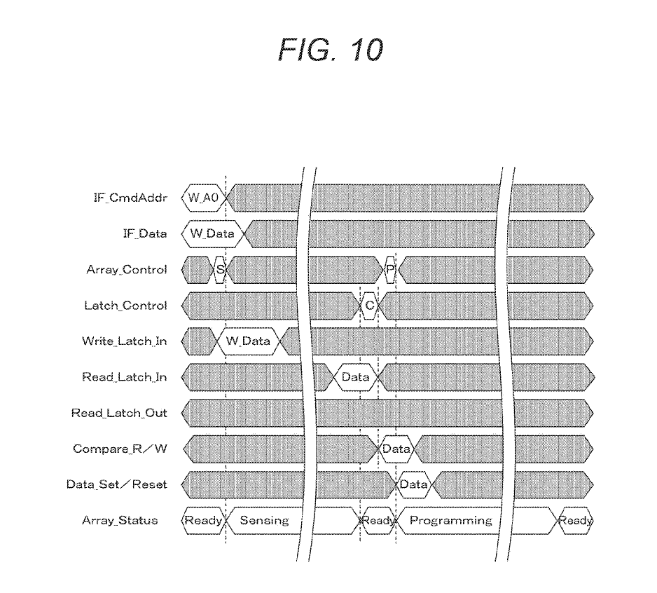

FIG. 9 is a flowchart showing an example of the procedures for processing a write command in a storage device 300 according to the embodiment of the present technology. Also, FIG. 10 is a timing chart showing an example of the procedures for processing a write command in a storage device 300 according to the embodiment of the present technology. In this example case, an address designated by the IF_CmdAddr signal line 209 is the address #0 in the bank #0.

When the memory controller 200 outputs a write command and the address #0 (represented by “W_A0” in the chart) to the IF_CmdAddr signal line 209, processing of the write command starts. As well as issuing the write command, the memory controller 200 outputs write data (represented by “W_Data” in the chart) to the IF_Data signal line 208. The IF 320 outputs the received write data sequentially to a Write_Latch_In signal line 325 of the bank #0 (step S941).

At the same time as the start of the write data input, the IF 320 refers to the Array_Status signal line 326 of the bank #0, and waits until the value of the Array_Status signal line 326 switches to “Ready” (steps S942 and S943). When the Array_Status signal line 326 switches to “Ready” (Yes in step S942), the IF 320 outputs “0” to the Array-Address signal line 321 of the bank #0, and “Sense” to the Array_Control signal line 322 (step S944). As a result, the NVM array 311 starts a sense operation, and the Array_Status signal line 326 switches to “Sensing”.

After a certain time has passed, the Array_Status signal line 326 switches to “Ready”. At this point of time, the input of the data read from the NVM array 311 into the read latch 312 has been completed. The IF 320 stands by until the Array_Status signal line 326 switches to “Ready” (steps S945 and S946). When the Array_Status signal line 326 switches to “Ready” (Yes in step S945), the IF 320 transmits a control signal “C” to the Latch_Control signal line 323, to instruct the comparator 314 to output the data stored in the read latch 312 and the write latch 313. As a result, the read data obtained by a sense operation is output from the read latch 312 via a Compare_R signal line 315, and the write data from the write latch 313 is output via a Compare_W signal line 316 (step S947). The Compare_R signal line 315 and the Compare_W signal line 316 are subjected to an operation performed by the comparator 314, to be turned into the Data_Set signal line 317 and the Data_Reset signal line 318, and be input to the NVM array 311.

The IF 320 then outputs “Program” (represented by “P” in the chart) to the Array_Control signal line 322 of the bank #0 (step S948). As a result, the NVM array 311 starts a program operation, and the Array Status signal line 326 switches to “Programming”. When the program operation is completed, and the Array_Status signal line 326 returns to “Ready”. The IF 320 stands by until the Array_Status signal line 326 switches to “Ready” (steps S951 and S952). When the IF 320 confirms that the Array_Status signal line 326 has switched to “Ready” (Yes in step S951), the write command is completed.

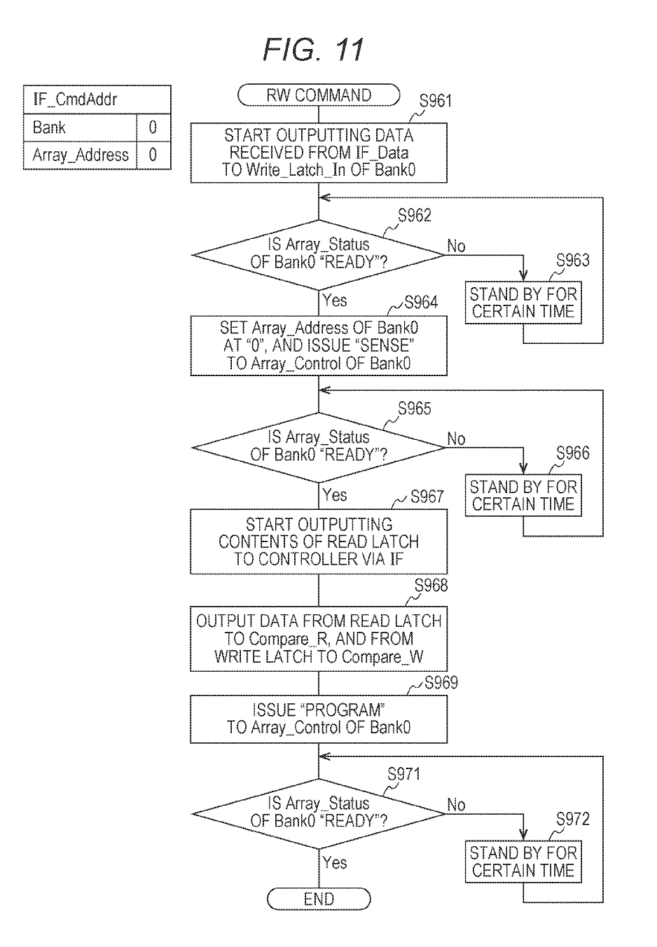

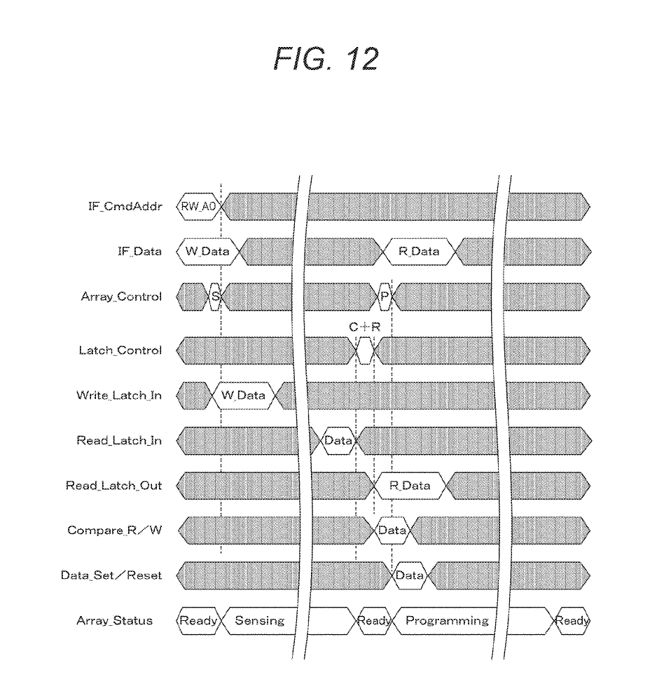

FIG. 11 is a flowchart showing an example of the procedures for processing a RW command in a storage device 300 according to the first embodiment of the present technology. Also, FIG. 12 is a timing chart showing an example of the procedures for processing a RW command in a storage device 300 according to the first embodiment of the present technology. In this example case, an address designated by the IF_CmdAddr signal line 209 is the address #0 in the bank #0.

When the memory controller 200 outputs a RW command and the address #0 (represented by “W_A0” in the chart) to the IF CmdAddr signal line 209, processing of the RW command starts. As well as issuing the RW command, the memory controller 200 outputs write data (represented by “W_Data” in the chart) to the IF Data signal line 208. The IF 320 outputs the received write data sequentially to a Write_Latch_In signal line 325 of the bank #0 (step S961).

At the same time as the start of the write data input, the IF 320 refers to the Array_Status signal line 326 of the bank #0, and waits until the value of the Array_Status signal line 326 switches to “Ready” (steps S962 and S963). When the Array_Status signal line 326 switches to “Ready” (Yes in step S962), the IF 320 outputs “0” to the Array-Address signal line 321 of the bank #0, and “Sense” to the Array_Control signal line 322 (step S964). As a result, the NVM array 311 starts a sense operation, and the Array_Status signal line 326 switches to “Sensing”.

After a certain time has passed, the Array_Status signal line 326 switches to “Ready”. At this point of time, the input of the data read from the NVM array 311 into the read latch 312 has been completed. The IF 320 stands by until the Array_Status signal line 326 switches to “Ready” (steps S965 and S966). When the Array_Status signal line 326 switches to “Ready” (Yes in step S965), a control signal “C+R” is transmitted to the Latch_Control signal line 323. As a result, the data stored in the read latch 312 and the write latch 313 is output to the comparator 314 (step S968), and is also output to the Read_Latch_Out signal line 324. The data output to the Read_Latch_Out signal line 324 is output from the IF 320 to the memory controller 200 via the IF_Data signal line 208 (step S967). The Compare_R signal line 315 and the Read_Latch_Out signal line 324 are independent of each other, and can be simultaneously operated.

The IF 320 then outputs “Program” (represented by “P” in the chart) to the Array Control signal line 322 of the bank #0 (step S969). As a result, the NVM array 311 starts a program operation, and the Array_Status signal line 326 switches to “Programming”. When the program operation is completed, and the Array_Status signal line 326 returns to “Ready”. The IF 320 stands by until the Array_Status signal line 326 switches to “Ready” (steps S971 and S972). When the IF 320 confirms that the Array_Status signal line 326 has switched to “Ready” (Yes in step S971), the RW command is completed.

As described above, in the processing of a RW command, the same operation as that with a write command is performed until data is read out to the read latch 312, but the data stored in the read latch is output not only to the comparator 314 but also to the Read_Latch_Out signal line 324. Accordingly, a RW command enables writing and reading at the same address in the same execution time as that with a write command.

It should be noted that step S964 is an example of the memory reading step of the claims. Also, step S967 is an example of the read data outputting step of the claims. Also, step S969 is an example of the memory writing step of the claims.

### [Operations of the Host Computer and the Memory Controller]

The memory controller 200 receives a command and an address from the host computer 100 via the Host_CmdAddr signal line 109. The host computer 100 transmits at least two kinds of commands: a Host_WRITE command for writing data into a storage device 300, and a Host READ command for reading from a storage device 300. In doing so, the host computer 100 transmits the address of the access target of these commands. At the same time as the write command transmission, the host computer 100 also outputs write data to the memory controller 200 via the Host_Data signal line 108.

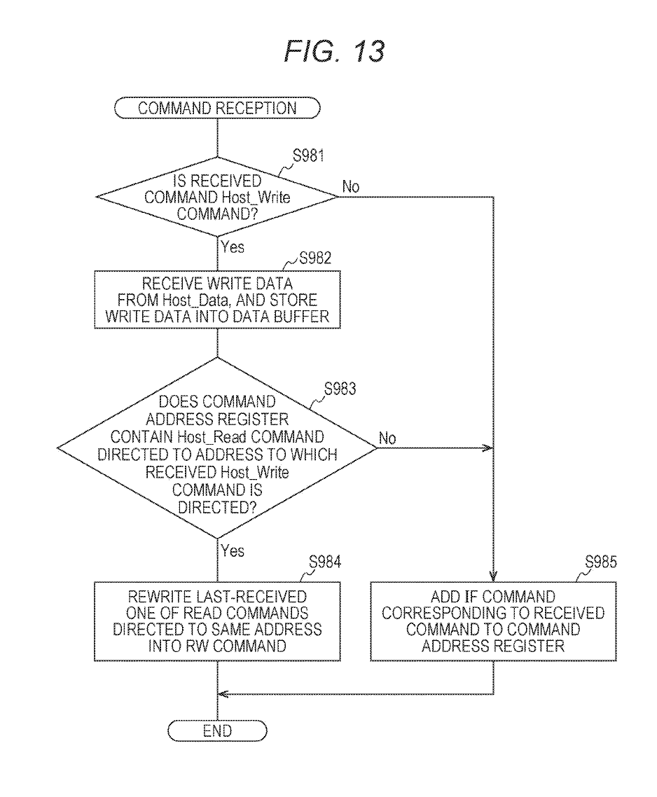

FIG. 13 is a flowchart showing an example of the procedures in a command reception process to be performed by the memory controller 200 according to the first embodiment of the present technology. The memory controller 200 starts the process shown in this flowchart every time the memory controller 200 receives a command from the host computer 100.

If a command that is not a Host_WRITE command is received (No in step S981), the signal from the Host_CmdAddr signal line 109 is stored into the command address register 210 (step S985).

If the memory controller 200 receives a Host_WRITE command (Yes in step S981), the memory controller 200 receives write data from the Host_Data signal line 108, and stores the write data into the data buffer 220 (step S982). A check is then made to determine whether the command address register 210 contains read commands directed to the address to which the received Host_WRITE command is directed. If the command address register 210 does not contain any of such read commands (No in step S983), the write command and the received address are added to the command address register 210. If the command address register 210 contains such read commands (Yes in step S983), the last-received one of the read commands directed to the same address is rewritten and turned into a RW command (step S984). Then, the data that has been received together with the Host_WRITE command and been stored into the data buffer 220 is set as the write data corresponding to this RW command.

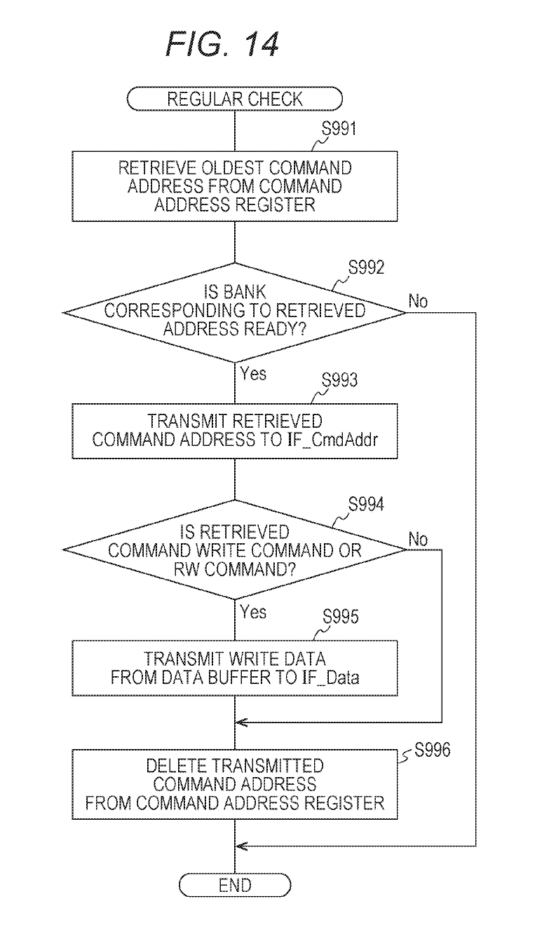

FIG. 14 is a flowchart showing an example of the procedures in a command transmission process to be performed by the memory controller 200 according to the first embodiment of the present technology. The memory controller 200 processes instructions stored in the command address register 210.

The memory controller 200 fetches the oldest (or the first-added) command address from the command address register 210 at regular time intervals (step S991). The memory controller 200 then refers to the status register 230, to determine whether the bank corresponding to the fetched address is “Ready”. If the bank is not “Ready” (No in step S992), the memory controller 200 ends the process. If the bank is “Ready” (Yes in step S992), the fetched command address is transmitted to the IF_CmdAddr signal line 209 (step S993). If the fetched command is a write command or a RW command (Yes in step S994), the write data that has been received together with the Host_WRITE command from the host computer 100 is stored in the data buffer 220. Therefore, the data is transmitted to the IF Data signal line 208 (step S995). The memory controller 200 deletes the last-transmitted command address from the command address register 210 (step S996), and ends the process.

Through the above series of procedures, the memory controller 200 determines whether a Host_WRITE command directed to the same address has been received, before transmitting a read command corresponding to a Host_READ command from the host computer 100 to the IF 320. For such a Host_WRITE command, the memory controller 200 uses a RW command, so that the processing time can be made shorter than that in a case where a read command and a write command are executed separately from each other.

As described above, according to the first embodiment of the present technology, a read command and a write command directed to the same address are replaced with a RW command. Thus, processing can be performed at higher speed.

### 2. Second Embodiment

As described above in the first embodiment, the IF Data signal line 208 is a data bus shared among banks. While writing or reading is being performed in a bank, another command may be issued to another bank. In such a manner, concurrent operations might be performed. In the first embodiment, however, data collisions need to be avoided when a read command or a write command is issued to another bank after a RW command is issued to a bank. Specifically, the memory controller 200 needs to adjust the command issuance intervals so that an output of read data in response to a RW command and an input/output of data in response to the next command will not collide with each other. Particularly, in a case where the time required for a sense operation varies, it is difficult to avoid data collisions. In view of this, a second embodiment is to define a DATAOUT command for a storage device 300 only to output data from the read latch 312 to the IF 320, and enable the similar operation to that with a RW command by combining a write command and the DATAOUT command. It should be noted that the DATAOUT command is an example of the command for outputting the read data stored in the read data holding unit to the requester in the claims.

### [DATAOUT Command]

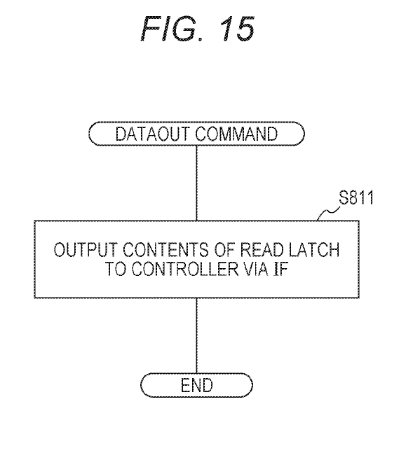

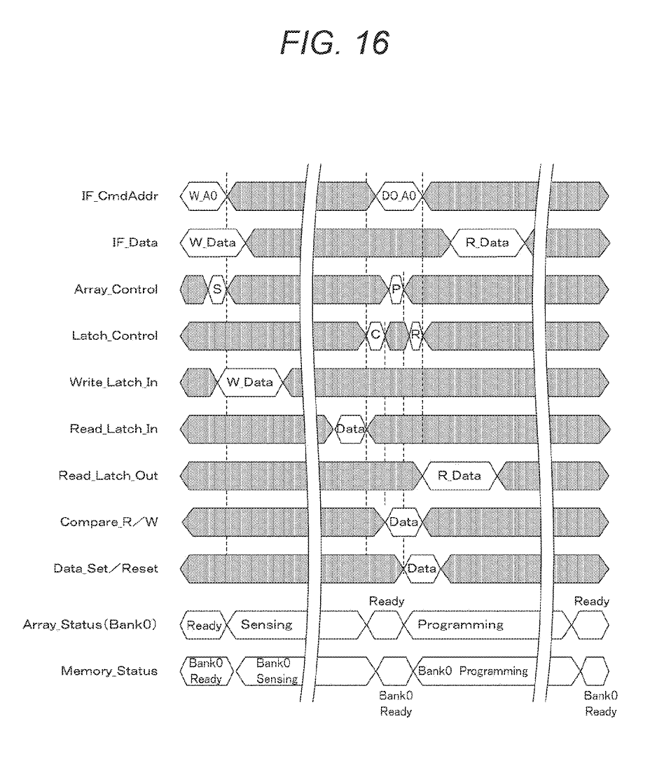

FIG. 15 is a flowchart showing an example of the procedures for processing a DATAOUT command in a storage device 300 according to the second embodiment of the present technology. Also, FIG. 16 is a timing chart showing an example of the procedures for processing a DATAOUT command in a storage device 300 according to the second embodiment of the present technology. In this example case, both a write command and a DATAOUT command are issued to the address #0 of the bank #0.

When the IF 320 receives a DATAOUT command, the IF 320 outputs the contents of the read latch 312 to the memory controller 200 (step S811). The memory controller 200 first issues a write command. After sensing a change in the state of the NVM array 311 from “Sensing” to “Ready” through the Memory Status signal line 207, the memory controller 200 issues a DATAOUT command (represented by “DO_A0” in the chart). As a result, data can be output from the read latch 312 while writing from the write latch 313 into the NVM array 311 is being performed (while the Array Status signal line 326 is “Programming”). That is, writing and reading at the same address can be performed in the similar execution time to that with a write command, as in the case with a RW command.

It should be noted that in the above described example, the DATAOUT command is also issued together with the address “0”, like the other commands, but the DATAOUT command is not to access the NVM array 311, and therefore, requires only a bank number for execution. In view of this, only the portion indicating a bank in the address bit string may be output.

In the first embodiment, the data output from the Read_Latch_Out signal line 324 is started immediately after the Array_Status signal line 326 switches to “Ready”. In the second embodiment, however, the output of read data is slightly delayed. This is because data is output after the IF 320 recognizes a DATAOUT command in the second embodiment. Also, the function of one RW command is achieved with a combination of two commands in the second embodiment, and therefore, more command buses are occupied than in the first embodiment.

As described above, according to the second embodiment of the present technology, a read command and a write command directed to the same address are replaced with a combination of a write command and a DATAOUT command. Thus, processing can be performed at higher speed.

### 3. Third Embodiment

The above described first embodiment is a method that has a great speed increasing effect in that data can be output in the same execution time as that with a write command. However, write data is first input, and read data is output later. Therefore, the data sequence in the IF_Data signal line 208 is the reverse of that in a conventional case where a read command and a write command are sequentially executed. As a result, the control from the memory controller 200 might become complicated depending on the configuration of the memory system.

In view of this, a third embodiment provides a method for increasing the processing speed while maintaining the same data input/output sequence as in a conventional case where a read command and a write command are sequentially executed. Specifically, a BLIND WRITE (BW) command that eliminates the sense operation to be performed first in writing is employed in addition to a conventional read command and a conventional write command.

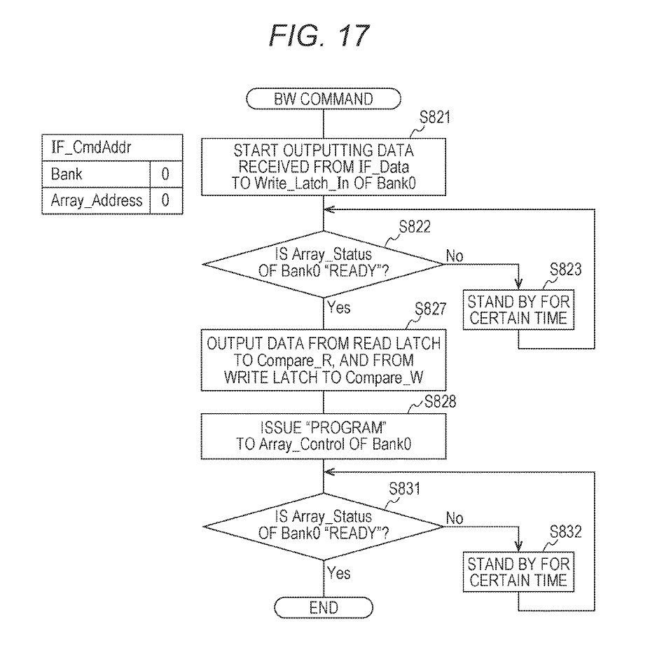

FIG. 17 is a flowchart showing an example of the procedures for processing a BW command in a storage device 300 according to the third embodiment of the present technology. It should be noted that a BW command is an example of the command for performing writing without storing new data into the read data holding unit with respect to the write target address in the claims.

The processing of the BW command is the same as the procedures for processing a conventional write command, except that the procedure for outputting “Sense” to the Array_Control signal line 322 and the next procedure for checking the Array_Status signal line 326 are skipped. That is, steps S944 through S946 are eliminated from the flowchart shown in FIG. 9. Therefore, the procedures are not explained herein. In the third embodiment, the sense operation is skipped, and a value already stored in the read latch 312 is output to the Compare_R signal line 315.

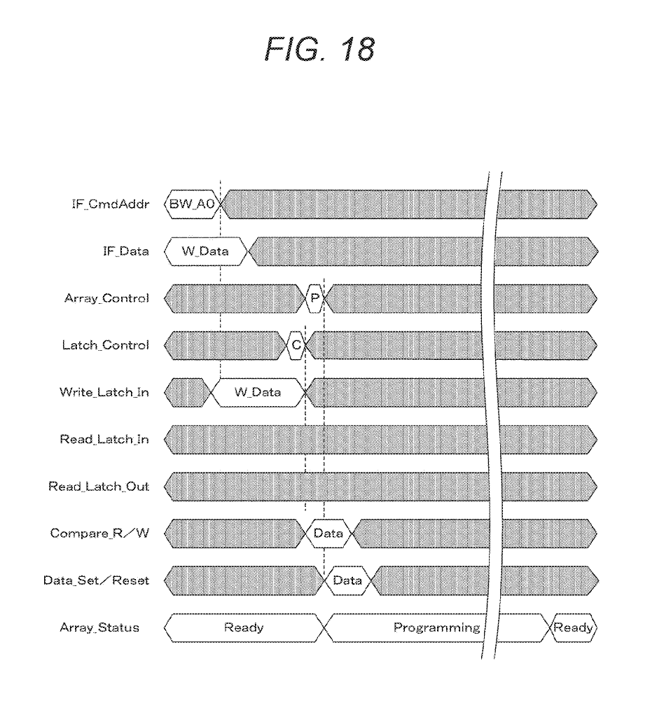

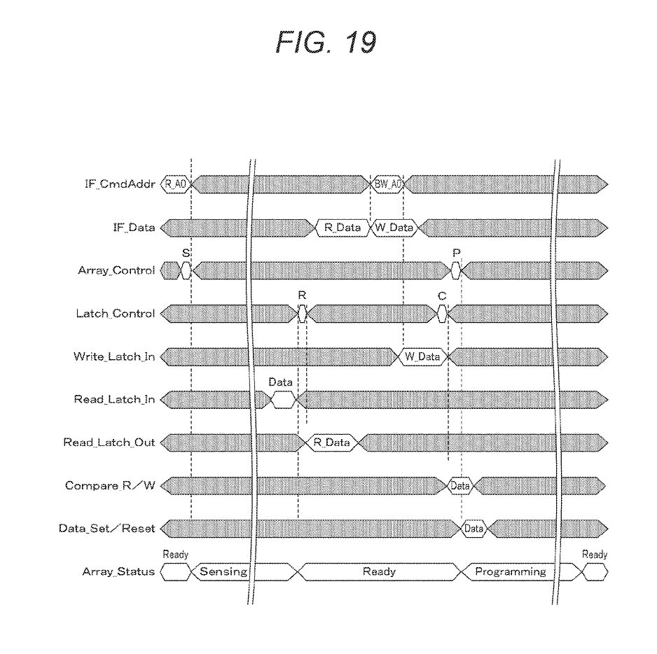

FIG. 18 is a timing chart showing an example of the procedures for processing only a BW command in a storage device 300 according to the third embodiment of the present technology. Also, FIG. 19 is a timing chart showing an example of the procedures for processing a BW command immediately after a read command in a storage device 300 according to the third embodiment of the present technology.

As a read command is processed first, read data is stored in the read latch 312. Then, in the processing of the BW command, the sense operation is not performed, and a value already stored in the read latch 312 is used in the comparison to be performed at the comparator 314. Accordingly, the processing time required for the sense operation can be eliminated. Also, the processing sequence is the similar to that in a conventional case where a read command and a write command are sequentially performed, and accordingly, complicated control can be avoided.

As described above, according to the third embodiment of the present technology, a read command and a write command directed to the same address are replaced with a combination of a read command and a BW command. Thus, processing can be performed at higher speed.

### 4. Fourth Embodiment

In the above described first embodiment, the memory controller 200 stores instructions from the host computer 100, and replaces a read command and a write command directed to the same address are replaced with another command. Ina fourth embodiment, this process is performed by the IF 320 of a storage device 300.

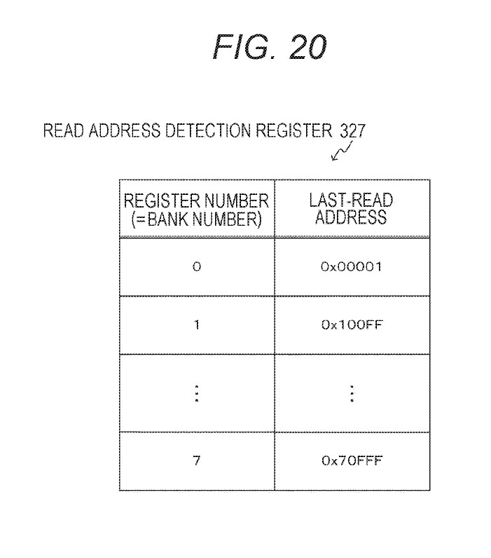

FIG. 20 is a table showing an example configuration of a read address detection register 327 according to the fourth embodiment of the present technology. This read address detection register 327 is provided in the IF 320. One register number is allotted to each bank, and the read address detection register 327 is a register that stores the addresses at which reading has been last performed in the respective banks. In the fourth embodiment, this read address detection register 327 is used to switch the contents of a write process.

It should be noted that the read address detection register 327 is an example of the address match detecting unit of the claims.

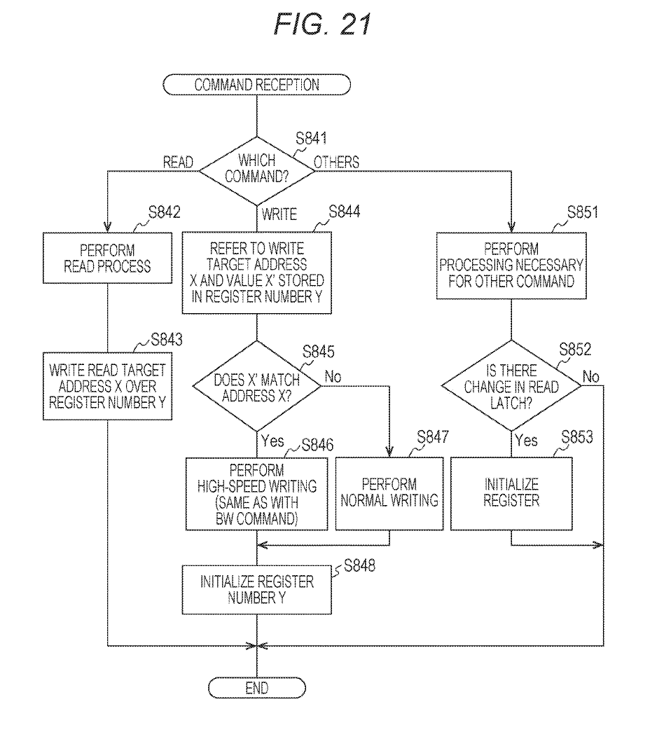

FIG. 21 is a flowchart showing an example of the procedures in a process to be performed by the IF 320 of a storage device 300 according to the fourth embodiment of the present technology. In this example, an address X belongs to a bank Y.

When a read command is output to the IF CmdAddr signal line 209 (READ in step S841), the IF 320 performs a process in a similar manner to a conventional read command (step S842). After that, the read target address is stored into the read address detection register 327. Specifically, in a case where the address X belongs to the bank Y, after a read process is performed at the address X, the register number Y is written over X (step S843).

When a write command is output to the IF_CmdAddr signal line 209 (WRITE in step S841) , the value corresponding to the write target bank is read from the read address detection register 327, and is compared with the write target address (step S844). If the value matches the address (Yes in step S845), the IF 320 performs a process in a similar manner to a BW command (step S846). If the value does not match the address (No in step S845), on the other hand, the IF 320 performs a process in a similar manner to a conventional write command (step S847). In a case where writing is performed at the same address as the last-read address, a sense operation is performed during a read process. Therefore, data read from the NVM array 311 is stored in the read latch 312. Thus, the value in the read latch 312 can be referred to as a Compare_R signal without a sense operation, and correct writing can be performed.

After writing is performed in this manner, the value in the NVM array 311 has already been updated. Even if a write command is next issued to the same address, the value in the read latch 312 can no longer be used as a Compare_R signal. Therefore, the IF 320 initializes the value in the read address detection register 327 with an invalid address (step S848).

In some cases, the IF 320 processes a command that is neither a read command nor a write command (OTHERS in step S841). For example, there may be a command for suspending memory access and entering a low power consumption state. If there is a possibility of change in the read latch 312 with such a command (Yes in step S852), the read address detection register 327 is initialized (step S853). Thus, an incorrect value in the read latch 312 will not be referred to as the value of the Compare_R signal line 315 the next time a write command is received.

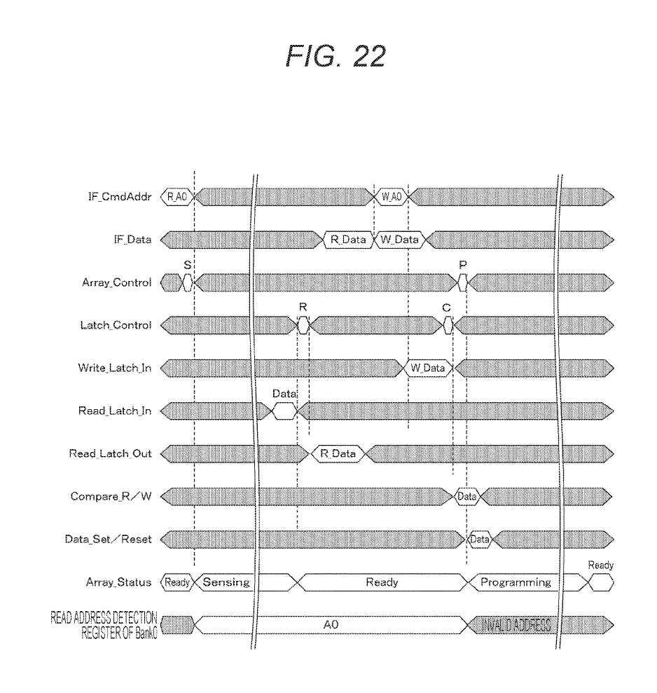

FIG. 22 is a timing chart showing an example of the procedures in a high-speed write process according to the fourth embodiment of the present technology. When the first read command (represented by “R_A0” in the chart) is received, the target address “0” is stored. After a write command (represented by “W_A0” in the chart) directed to the same address is received, writing is performed without any sense operation.

As described above, according to the fourth embodiment of the present technology, the IF 320 replaces a read command and a write command directed to the same address with a combination of a read command and a BW command. Thus, processing can be performed at higher speed.

### 5. Fifth Embodiment

In the above described first embodiment, the memory controller 200 detects a Host_WRITE command issued after a Host_READ command to the same address, and a RW command is then issued. Ina fifth embodiment, on the other hand, the host computer 100 can recognize writing to be performed at the address where reading has just been performed. In such a case, the host computer 100 instructs the memory controller 200 to issue a RW command.

A Host RW_command, an address, and write data are transmitted from the host computer 100 to the memory controller 200. Upon receipt of the Host RW_command, the memory controller 200 performs the similar process to that shown in FIG. 13. Specifically, the RW command and the received address are added to the command address register 210, and the write data is stored into the data buffer. After that, the RW command and the data are transmitted to the IF 320 through similar procedures to those shown in FIG. 14.

It should be noted that the host computer 100 may issue the DATAOUT command or the BW command described above in the second and third embodiments, instead of the RW command.

As described above, according to the fifth embodiment of the present technology, the host computer 100 can recognize writing to be performed at the address where reading has just been performed, and instruct the memory controller 200 to issue a RW command or the like.

### 6. Sixth Embodiment

A nonvolatile memory is allowed only a limited number of rewrites. To effectively extend the life of each rewrite, the variation in the number of rewrites among the cells should be reduced. To manage the lives of rewrites in a nonvolatile memory, data is exchanged between a cell with a large number of rewrites and a cell with a small number of rewrites. This is a process known as wear leveling. Also, in a memory system, an area called a swap area is normally set in the address space, and the data in the main memory is temporarily saved in the swap area. A host computer reads the data saved in the swapping area and writes the data into the main memory, and also writes new data at the same address in the swap area. The host computer often performs this process called data swapping. A sixth embodiment concerns a method of speeding up the data swapping, using the BW command described above in the third embodiment.

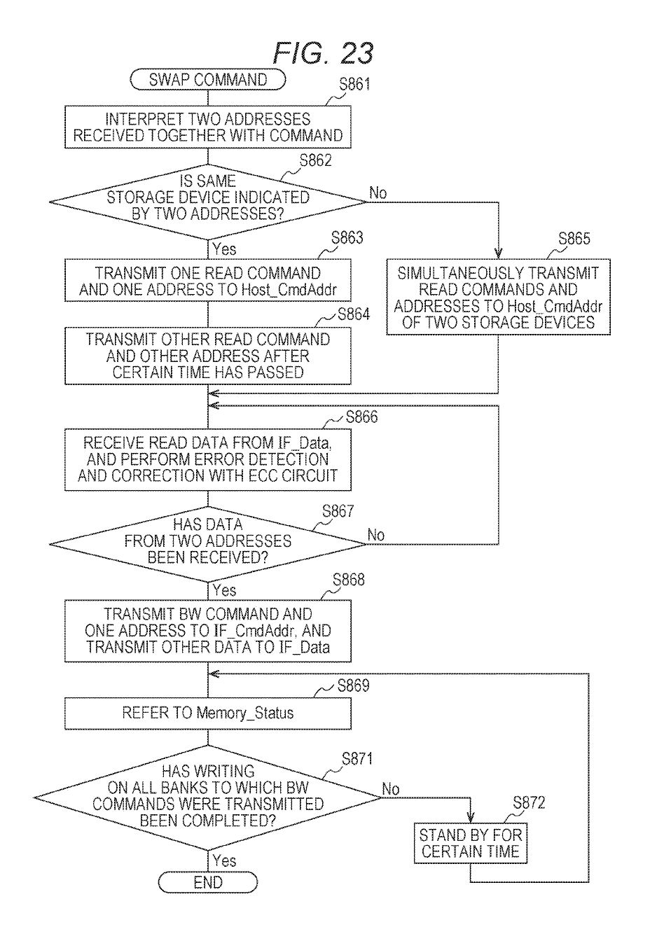

FIG. 23 is a flowchart showing an example of the procedures in a process to be performed by a memory controller 200 according to the sixth embodiment of the present technology. A host computer 100 transmits a SWAP command and two addresses as the swap targets to the memory controller 200 via the Host_CmdAddr signal line 109. Here, the two addresses indicate different banks or different memory devices.

Upon receipt of the SWAP command (step S861), the memory controller 200 issues read commands directed to the two addresses, to a storage device 300 via the IF_CmdAddr signal line 209. If the two addresses indicate the same storage device 300 (Yes in step S862), signals might collide with each other in the IF_CmdAddr signal line 209 or the IF Data signal line 208. Therefore, two read commands are issued at a necessary interval so as to avoid a collision between the two (steps S863 and S864). If the two addresses indicate different storage devices 300, and the IF_CmdAddr signal line 209 and the IF_Data signal line 208 are independent of each other, on the other hand, there is no possibility of a collision, and two read commands are issued at the same time (step S865).

After a certain time has passed, the memory controller 200 receives read data that is output from the IF_Data signal line 208. The memory controller 200 subjects the read data to error detection and correction being performed by the ECC circuit 240, and then stores the read data into the data buffer 220 (step S866). After the read data from the two addresses is stored into the data buffer 220 (Yes in step S867), BW commands are issued to the two addresses, and high-speed writing is performed (step S868).

After the transmission of the BW commands, the Memory Status signal line 207 is referred to (step S869), and a check is made to confirm that the two banks to which the two addresses belong have switched from “Programming” to “Ready” (steps S871 and S872). The process then comes to an end.

As described above, according to the sixth embodiment of the present technology, data swapping can be speeded up with BW commands.

### 7. Seventh Embodiment

In a nonvolatile memory, recorded values slightly change every time reading is performed. After reading is repeated a certain number of times, a read defect might occur. This is called read disturb. To prevent read disturb, data is rewritten after reading is performed a certain number of times. This is called refreshing. This refreshing is performed by detecting and correcting an error after data is read, and again performing writing at the same address. A seventh embodiment concerns a method of speeding up the refreshing, using the BW command described above in the third embodiment.

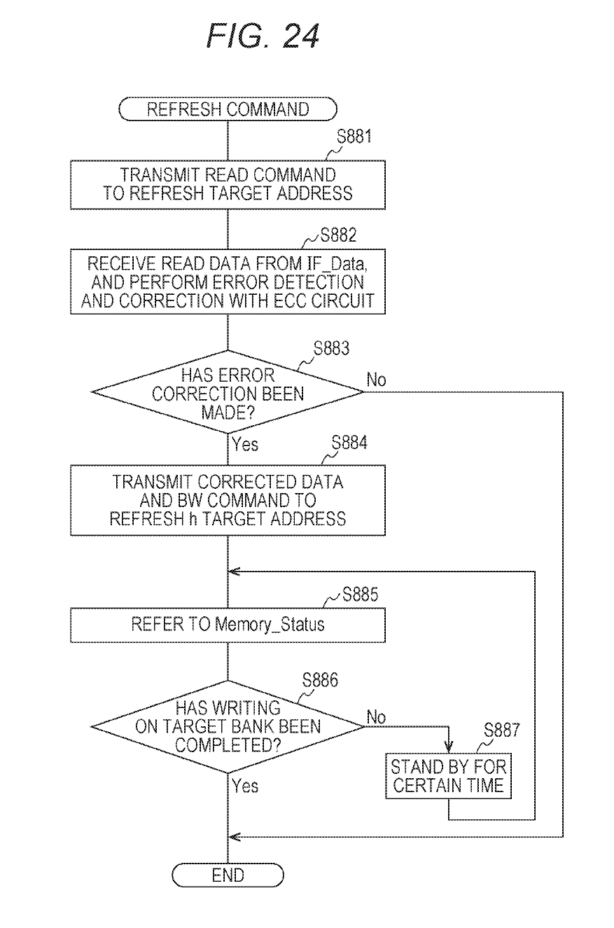

FIG. 24 is a flowchart showing an example of the procedures in a process to be performed by a memory controller 200 according to the seventh embodiment of the present technology. When the memory controller 200 receives a refresh command and an address from the host computer 100 via the Host_CmdAddr signal line 109, the procedures in this process start. First, a read command is transmitted, via the IF_CmdAddr signal line 209, to the address in the storage device 300 indicated by the address received from the host computer 100 (step S881). After a certain time has passed, read data that is output from the IF_Data signal line 208 is received, and the read data is subjected to error detection and correction by the ECC circuit 240 (step S882). The ECC circuit 240 also outputs a signal indicating whether error correction has been made. The memory controller 200 receives this signal. If error correction has not been made (or where read disturb has not occurred, and all the bits have been correctly read) (No in step S883), the refresh process is completed without any action. If error correction has been made (or where read disturb has occurred, and an incorrect value has been read) (Yes in step S883), on the other hand, corrected data and a BW command are transmitted to the address (step S884).

After the transmission of the BW command, the Memory Status signal line 207 is referred to (step S885), and a check is made to confirm that the bank has switched from “Programming” to “Ready” (steps S886 and S887). The process then comes to an end.

As a result, the read data stored in the read latch 312 is compared with the data error-corrected by ECC, and a write voltage is applied only to the corrected bit (s) through a program operation. Thus, the read disturb is corrected.

As described above, according to the seventh embodiment of the present technology, refreshing can be speeded up with a BW command.

It should be noted that the above described embodiments are examples for embodying the present technology, and the matter of the embodiments corresponds to the subject matter of the claims. Likewise, the subject matter of the claims corresponds to the matter under the same names as the subject matter of the claims in the embodiments of the present technology. However, the present technology is not limited to the embodiments, and various changes can be made to the embodiments without departing from the scope of the technology.

Also, the processing procedures described above in the embodiments may be regarded as a method involving the series of these procedures, or may be regarded as a program for causing a computer to carryout the series of these procedures or a recording medium storing the program. This recording medium may be a Compact Disc (CD), a MiniDisc (MD), a Digital Versatile Disc (DVD), a memory card, or a Blu-ray (registered trademark) Disc, for example.

It should be noted that the advantageous effects described in this specification are merely examples, and the advantageous effects of the present technology may include other effects.

It should be noted that the present technology may also be embodied in the configurations described below.

(1) A storage device including:

a memory reading unit that reads data stored at a predetermined address in a memory array, and stores the data read from the memory array into a read data holding unit, the data read from the memory array being stored as read data;

a read data outputting unit that outputs the read data stored in the read data holding unit to the requester;

a memory writing unit that performs writing at a write target address in the memory array in accordance with write data to be written into the memory array and the read data; and

a control unit that controls the memory writing unit to operate only when the write target address matches the predetermined address.

(2) The storage device of (1), wherein, when a command for sequentially performing reading and writing at the same address in the memory array is issued, the control unit determines that the write target address matches the predetermined address.

(3) The storage device of (1), wherein, when a command for outputting the read data stored in the read data holding unit to a requester is issued, the control unit determines that the write target address matches the predetermined address.

(4) The storage device of (1), wherein, when a command for performing writing without storing new data with respect to the write target address into the read data holding unit is issued, the control unit determines that the write target address matches the predetermined address.

(5) The storage device of (1), wherein the control unit includes an address match detecting unit that detects a match between the write target address and the predetermined address, and determines whether the write target address matches the predetermined address.

(6) An information processing system including: a storage device, a memory controller that controls a request for access to the storage device, and a host computer that issues an access command for the storage device to the memory controller,

wherein the storage device includes:

a memory reading unit that reads data stored at a predetermined address in a memory array, and stores the data read from the memory array into a read data holding unit, the data read from the memory array being stored as read data;

a read data outputting unit that outputs the read data stored in the read data holding unit to the requester;

a memory writing unit that performs writing at a write target address in the memory array in accordance with write data to be written into the memory array and the read data; and

a control unit that controls the memory writing unit to operate only when the write target address matches the predetermined address.

(7) A storage control method including:

a memory reading step of reading data stored at a predetermined address in a memory array, and storing the data read from the memory array into a read data holding unit, the data read from the memory array being stored as read data;

a read data outputting step of outputting the read data stored in the read data holding unit to the requester; and

a memory writing step of performing writing at a write target address in the memory array in accordance with write data to be written into the memory array and the read data, only when the write target address matches the predetermined address in the memory array.

### REFERENCE SIGNS LIST

100 Host computer
200 Memory controller
210 Command address register
220 Data buffer
230 Status register
240 ECC circuit
300 Storage device
310 Bank
311 NVM array
312 Read latch
313 Write latch
314 Comparator
327 Read address detection register

1. A storage device comprising:
a memory reading unit configured to read data stored at a predetermined address in a memory array, and store the data read from the memory array into a read data holding unit, the data read from the memory array being stored as read data;
a read data outputting unit configured to output the read data stored in the read data holding unit to a requester;
a memory writing unit configured to perform writing at a write target address in the memory array in accordance with write data to be written into the memory array and the read data; and
a control unit configured to control the memory writing unit to operate only when the write target address matches the predetermined address.

2. The storage device according to claim 1, wherein, when a command for sequentially performing reading and writing at the same address in the memory array is issued, the control unit determines that the write target address matches the predetermined address.

3. The storage device according to claim 1, wherein, when a command for outputting the read data stored in the read data holding unit to a requester is issued, the control unit determines that the write target address matches the predetermined address.

4. The storage device according to claim 1, wherein, when a command for performing writing without storing new data with respect to the write target address into the read data holding unit is issued, the control unit determines that the write target address matches the predetermined address.

5. The storage device according to claim 1, wherein the control unit includes an address match detecting unit configured to detect a match between the write target address and the predetermined address, and determines whether the write target address matches the predetermined address.

6. An information processing system comprising: a storage device, a memory controller configured to control a request for access to the storage device, and a host computer configured to issue an access command for the storage device to the memory controller,
wherein the storage device includes:
a memory reading unit configured to read data stored at a predetermined address in a memory array, and store the data read from the memory array into a read data holding unit, the data read from the memory array being stored as read data;
a read data outputting unit configured to output the read data stored in the read data holding unit to a requester;
a memory writing unit configured to perform writing at a write target address in the memory array in accordance with write data to be written into the memory array and the read data; and
a control unit configured to control the memory writing unit to operate only when the write target address matches the predetermined address.

7. A storage control method comprising:
a memory reading step of reading data stored at a predetermined address in a memory array, and storing the data read from the memory array into a read data holding unit, the data read from the memory array being stored as read data;
a read data outputting step of outputting the read data stored in the read data holding unit to the requester; and
a memory writing step of performing writing at a write target address in the memory array in accordance with write data to be written into the memory array and the read data, only when the write target address matches the predetermined address in the memory array.
